(19) United States
(12) Patent Application Publication
(10) Pub. No.: US 2026/0147020 A1
(43) Pub. Date: May 28, 2026

(54) CURRENT SENSOR

(71) Applicant: Alps Alpine Co., Ltd., Tokyo (JP)

(72) Inventors: Manabu TAMURA, Miyagi-ken (JP); Chiaki UEDA, Miyagi-ken (JP)

(21) Appl. No.: 19/453,274

(22) Filed: Jan. 20, 2026

Related U.S. Application Data
(63) Continuation of application No. PCT/JP2024/006636, filed on Feb. 22, 2024.

(30) Foreign Application Priority Data
Jul. 28, 2023 (JP) 2023-123542

(51) Int. Cl. G01R 15/20; G01R 19/00

(52) U.S. Cl. CPC G01R 15/205; G01R 19/0092

(57) ABSTRACT

A current sensor including a busbar through which a current to be measured flows and a magnetic sensor disposed to detect a magnetic field generated by the busbar includes a conductor comprising a nonmagnetic material. The conductor is disposed opposite the busbar with the magnetic sensor interposed between the conductor and the busbar. The current sensor is capable of suppressing the occurrence of problems associated with frequency characteristics of the current sensor in which measurement errors increase due to the skin effect, which is influenced by the frequency of currents to be measured flowing through a busbar, and provides good measurement accuracy.

### CLAIM OF PRIORITY

This application is a Continuation of International Application No. PCT/JP2024/006636 filed on February 22, 2024, which claims benefit of Japanese Patent Application No. 2023-123542 filed on July 28, 2023. The entire contents of each application noted above are hereby incorporated by reference.

### BACKGROUND OF THE INVENTION

### 1. Field of the Invention

The present invention relates to a current sensor for measuring a current to be measured flowing through a busbar.

### 2. Description of the Related Art

In recent years, current sensors that measure currents to be measured flowing through various devices have been used to control power systems of vehicles or the like equipped with these devices. Such current sensors have a frequency-characteristics problem in that, when a current to be measured flowing through a busbar is alternating current, measurement errors increase due to the skin effect, which increases in proportion to the frequency of the current. To solve the frequency-characteristics problem, various approaches have been explored.

For example, Japanese Unexamined Patent Application Publication No. 2017-58275 describes a current sensor in which an insulating portion is provided in a primary conductor through which a current to be measured flows, in order to suppress the generation of eddy currents that affect frequency characteristics. International Publication WO 2018/142850 describes a current sensor in which a magnetoelectric conversion element is disposed at a position that does not face any of a plurality of surfaces of a current path through which a current to be measured flows, and in which the sensitivity axis direction of the magnetoelectric conversion element is aligned parallel to the thickness direction of the current path. Japanese Unexamined Patent Application Publication No. 2022-52554 describes a current detection device in which a pair of magnetic detection elements is disposed at asymmetric positions that avoid the center of the cross-section of a conductor through which a current to be measured flows and that are at mutually different distances from the cross-sectional center.

The current sensors and the current detection device described in Japanese Unexamined Patent Application Publication No. 2017-58275, International Publication WO 2018/142850 and Japanese Unexamined Patent Application Publication No. 2022-52554, however, have difficulties in sufficiently suppressing the occurrence of problems associated with frequency characteristics.

### SUMMARY OF THE INVENTION

The present invention provides a current sensor with good measurement accuracy capable of suppressing the occurrence of problems associated with frequency characteristics in which measurement errors increase due to the skin effect, which is influenced by the frequency of currents to be measured flowing through a busbar.

To solve the above-mentioned problems, the present invention is provided with the following configurations.

A current sensor including a busbar through which a current to be measured flows and a magnetic sensor disposed to detect a magnetic field generated by the busbar is provided. The current sensor includes a conductor comprising a nonmagnetic material, in which the conductor is disposed opposite the busbar with the magnetic sensor interposed between the conductor and the busbar.

By disposing a conductor comprising a nonmagnetic material opposite a busbar with a magnetic sensor interposed between the conductor and the busbar, at least part of a magnetic field caused by an eddy current generated in the busbar when a current to be measured flows through the busbar can be canceled out. Accordingly, the influence of the magnetic field caused by the eddy current can be reduced.

When a direction in which the busbar, the magnetic sensor, and the conductor are disposed is a first direction, a direction orthogonal to the first direction and in which the busbar extends is a second direction, and a direction orthogonal to the first direction and the second direction is a third direction, the conductor may be formed in a plate-like shape parallel to a plane defined by the second direction and the third direction.

In this case, when viewed in the first direction, the busbar and the magnetic sensor are preferably disposed inside ends of the conductor in the third direction.

This configuration facilitates the generation, in the conductor, of an eddy current that flows in the opposite direction to an eddy current generated in the busbar by the current to be measured flowing through the busbar. Accordingly, the frequency characteristics of the current sensor can be improved.

The nonmagnetic material may be aluminum. Aluminum is lightweight and inexpensive, and thus enables low-cost production of lightweight current sensors.

The current sensor may include a magnetic shield. Such a magnetic shield reduces magnetic noise, and increases the measurement accuracy of the current sensor.

The magnetic shield may comprise a plate-shaped first magnetic shield plate, and the first magnetic shield plate may be disposed between the magnetic sensor and the conductor.

This configuration enables the magnetic shield to be disposed in the vicinity of the magnetic sensor, and thus increases the effectiveness of reducing magnetic noise by the magnetic shield.

The magnetic shield may comprise a plate-shaped first magnetic shield plate and a plate-shaped second magnetic shield plate, and the magnetic sensor and the busbar may be disposed between the first magnetic shield plate and the second magnetic shield plate.

This configuration reduces magnetic noise to the magnetic sensor disposed between the first magnetic shield plate and the second magnetic shield plate. In addition, measurement of a magnetic field generated when a current to be measured flows through the busbar is not obstructed by the second magnetic shield plate. Accordingly, the current sensor with good measurement accuracy can be provided.

When a direction in which the busbar, the magnetic sensor, and the conductor are disposed is a first direction, a direction in which the busbar extends is a second direction, and a direction orthogonal to the first direction and the second direction is a third direction, the magnetic shield may have a U shape when viewed in the second direction, and have side wall portions spaced apart on both sides of the magnetic sensor and the busbar in the third direction and a bottom portion disposed opposite the magnetic sensor in the first direction with the busbar interposed between the bottom portion and the magnetic sensor.

A U-shaped magnetic shield provided with a bottom portion and side wall portions enables efficient blocking of magnetic noise from a third direction in addition to a first direction.

The current sensor may include a pair of magnetic sensors whose detection directions are opposite to each other, and the magnetic field generated by the busbar may be detected as a difference between magnetic fields detected by the pair of magnetic sensors.

By using a difference between magnetic fields detected by a pair of magnetic sensors whose detection directions are opposite to each other, magnetic noise can be reduced, and thus the measurement accuracy of the current sensor can be increased.

A current sensor according to the invention can reduce, with a conductor comprising a nonmagnetic material, the influence of eddy currents generated when alternating current flows through a busbar. Reduced skin effect suppresses measurement errors caused by the frequency of a current to be measured, and thus a current sensor with good measurement accuracy can be provided.

### BRIEF DESCRIPTION OF THE DRAWINGS

FIG. 1 is a perspective view of a current sensor according to a first embodiment, illustrating its external appearance;

FIG. 2 is an exploded perspective view illustrating a configuration of the current sensor in FIG. 1;

FIG. 3 is a cross-sectional view schematically illustrating the configuration of the current sensor in FIG. 1;

FIG. 4 is a schematic view illustrating the skin effect;

FIG. 5 is a schematic view illustrating a mechanism of how a conductor acts on a busbar;

FIG. 6 is a graph showing phase characteristics of a known current sensor and the current sensor according to the first embodiment;

FIG. 7 is a cross-sectional view schematically illustrating a configuration of a current sensor according to a second embodiment;

FIG. 8 is a cross-sectional view schematically illustrating a modification of the current sensor in FIG. 7;

FIG. 9 is a graph showing phase characteristics of a known current sensor and the current sensor according to the second embodiment;

FIG. 10 is a graph showing the relationship between the distance between the conductor and the busbar and phase characteristics of the current sensor according to the second embodiment;

FIG. 11 is a plan view schematically illustrating a configuration of a current sensor according to a third embodiment;

FIG. 12 is a plan view schematically illustrating a modification of the current sensor in FIG. 11; and

FIG. 13 is a plan view schematically illustrating another modification of the current sensor in FIG. 11.

### DESCRIPTION OF THE PREFERRED EMBODIMENTS

### First Embodiment

Hereinafter, embodiments of the present invention will be described with reference to the attached drawings. In each drawing, the same numerals are given to the same components, and their descriptions are omitted. Reference coordinates are shown in the drawing as appropriate to indicate the positional relationships among the respective components. In the reference coordinates, a width direction of a busbar is referred to as an X direction (third direction), a busbar extending direction orthogonal to the X direction is referred to as a Y direction (second direction), and a direction that is orthogonal to the X direction and the Y direction is referred to as a Z direction (first direction). The X direction denotes a direction of a sensitivity axis of a magnetic sensor, and the Y direction and the Z direction are orthogonal to the sensitivity axis.

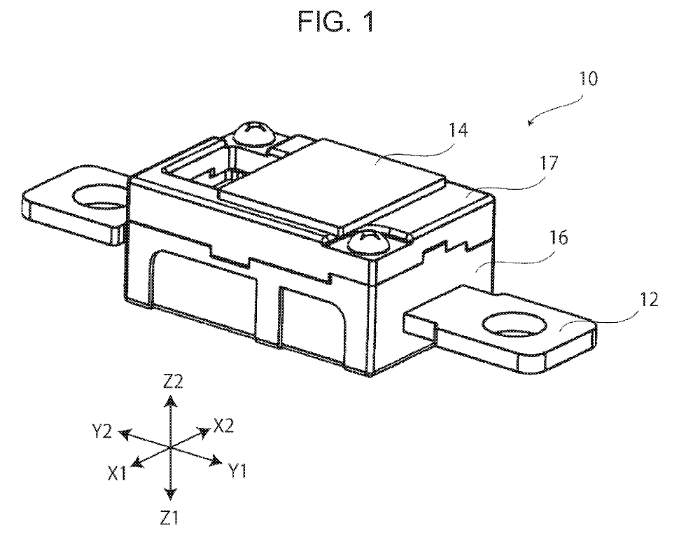

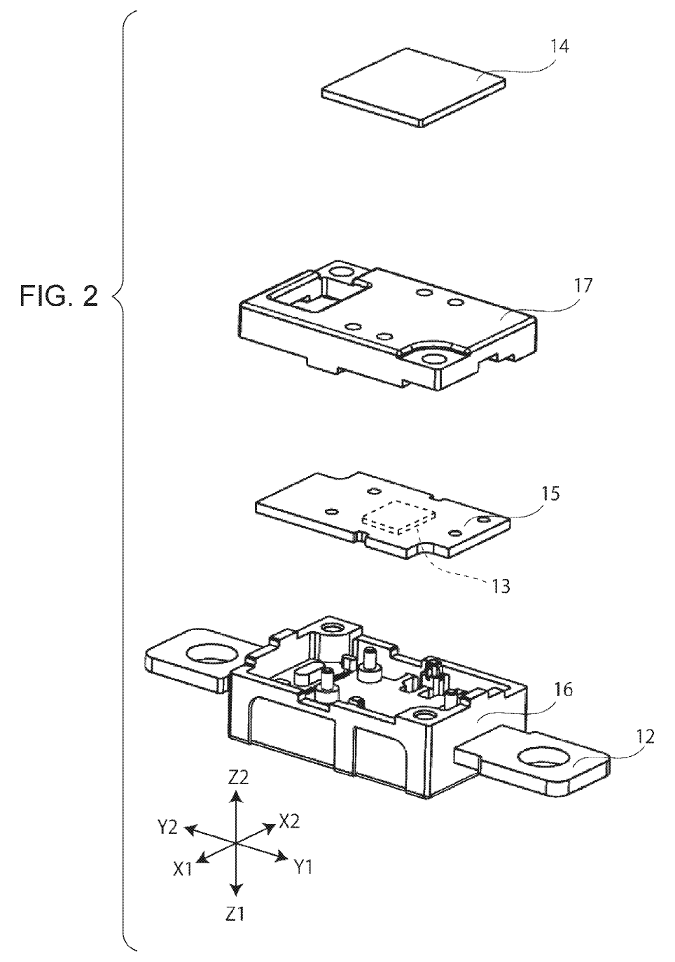

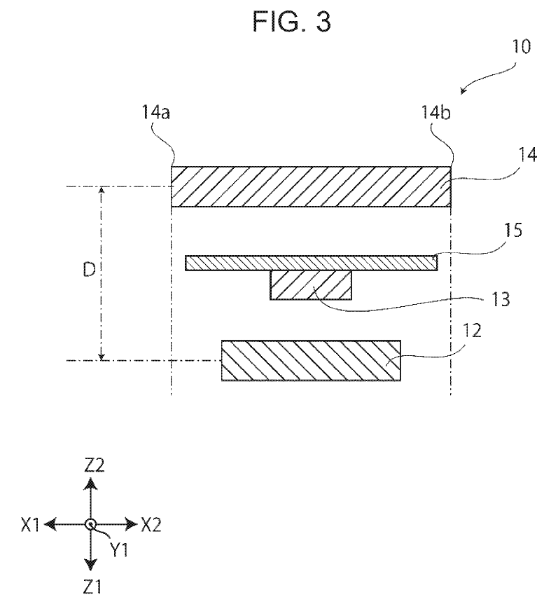

FIG. 1 is a perspective view of a coreless current sensor 10 without a core according to the embodiment, illustrating its external appearance. FIG. 2 is an exploded perspective view illustrating a configuration of the current sensor 10. FIG. 3 is a cross-sectional view schematically illustrating the configuration of the current sensor 10. As illustrated in the drawings, the current sensor 10 includes a busbar 12, a magnetic sensor 13, a conductor 14, a substrate 15, a housing 16, and a cover section 17.

The busbar 12 is a plate-shaped conductor comprising copper, brass, aluminum, or a similar material, and through which a current to be measured flows. The busbar 12 is provided in the housing 16 as illustrated in FIGS. 1 and 2. The busbar 12 has, for example, a structure fixed to the housing 16 by insert molding, or a structure attachable to the housing 16 by fitting into the housing 16.

The housing 16 has a storage space that is open in the Z2 direction. The substrate 15 with the magnetic sensor 13 attached thereto is stored in the storage space. The substrate 15 comprises epoxy glass, ceramic, or a similar material, and is fixed to the housing 16 by using a fixing member (not illustrated).

In addition, the cover section 17 is disposed on the Z2 direction side of the housing 16 so as to block the opening of the storage space.

The magnetic sensor 13 is capable of detecting a magnetic field that is generated by the busbar 12 when a current to be measured flows. The magnetic sensor 13 is disposed to face the busbar 12 in the Z direction. In the configuration in FIG. 3, when a current to be measured flows through the busbar 12, a magnetic field having a large X-direction component is generated on the Z2-direction side of the busbar 12. Accordingly, it is necessary to dispose the magnetic sensor 13 such that the detection surface of the magnetic sensor 13 faces the busbar 12 and the sensitivity axis is oriented in the X direction.

The magnetic sensor 13 according to the embodiment uses a magnetoresistance effect element as a detection element. The surface of the magnetic sensor 13 that faces the busbar 12 is the detection surface. The magnetic sensor 13 can detect magnetic components in a direction parallel to the detection surface. In other words, the sensitivity axis is directed parallel to the detection surface. Accordingly, by disposing the magnetic sensor 13 such that the detection surface of the magnetic sensor 13 faces the busbar 12 and the sensitivity axis is directed in the X direction, an induced magnetic field from the busbar 12 can be accurately detected. In the magnetic sensor 13, as the detection element, a Hall element or the like may be used other than the magnetoresistance effect element. It should be noted that the sensitivity-axis direction with respect to the detection surface changes depending on the detection element used in the magnetic sensor 13, and accordingly, the arrangement of the magnetic sensor 13 needs to be changed as appropriate.

The conductor 14 comprises a nonmagnetic material and is formed in a rectangular plate-like shape as will be described below. The conductor 14 is disposed opposite the busbar 12 with the magnetic sensor 13 between the conductor 14 and the busbar 12 in the Z direction. By providing the conductor 14 comprising a nonmagnetic material, the influence of eddy currents generated in the busbar 12 when a current flows through the busbar 12 can be reduced, and thus the frequency characteristics of the current sensor 10 are improved. The reason for this will be described later. In the current sensor 10, the conductor 14 is disposed on the Z2-side surface of the cover section 17.

In such coreless-type current sensors, many current sensors include a magnetic shield plate formed in a plate-like shape, as described in the second embodiment below. Such a magnetic shield plate is a magnetic material, whereas the conductor 14 is a nonmagnetic material. Accordingly, the magnetic shield plate and the conductor 14 are completely different components in that the components are a magnetic material or a nonmagnetic material.

Here, “nonmagnetic material” refers to substances such as copper (Cu), aluminum (Al), titanium (Ti), and the like, and in the present invention, substances other than ferromagnetic materials are referred to as non-magnetic materials. Among the exemplary nonmagnetic materials, aluminum is preferable because it is lightweight and inexpensive, and is advantageous in terms of weight reduction and manufacturing costs.

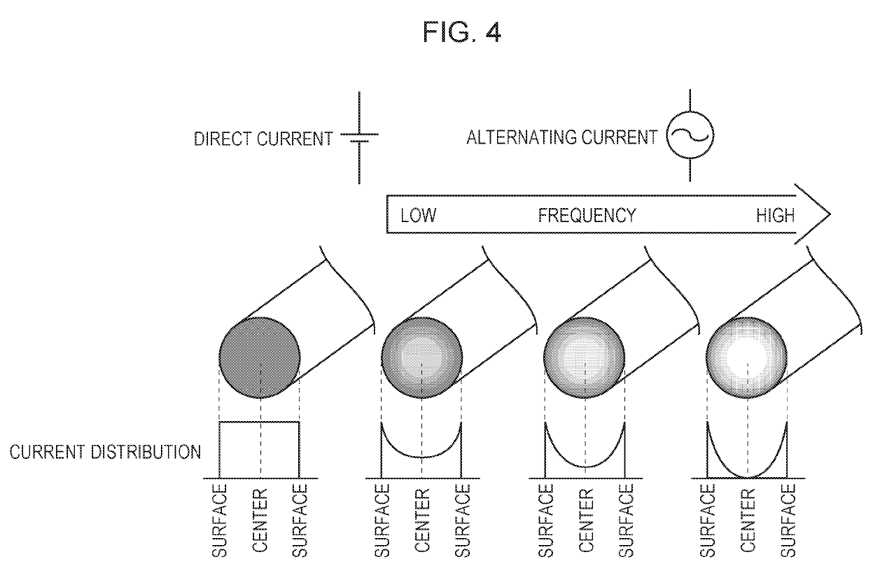

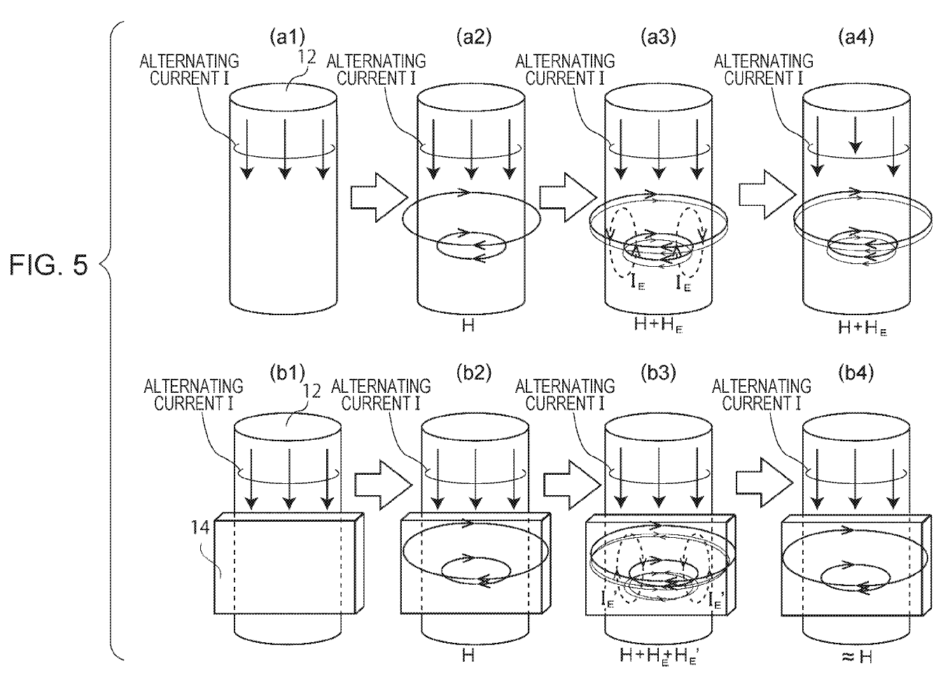

The conductor 14 is, as illustrated in FIG. 2, formed in a rectangular plate-like shape having long sides in the Y direction and is parallel to the XY plane defined in the X direction and the Y direction. The busbar 12 and the magnetic sensor 13 are disposed, as illustrated in FIG. 3, when viewed in the Z direction (first direction), inside ends 14a and 14b of the conductor 14 in the X direction (third direction). In other words, when viewed in the Z direction, the busbar 12 and the magnetic sensor 13 are disposed between the alternating long and short dashed lines extending in the Z1 direction from the respective ends 14a and 14b of the conductor 14 in the X direction illustrated by the alternating long and short dashed lines in FIG. 3. With this configuration, the frequency characteristics of the coreless current sensor 10 are improved. The improvement in the frequency characteristics of the current sensor 10 achieved by providing the conductor 14 will be described below with reference to FIGS. 4 and 5.

FIG. 4 is a schematic view illustrating the skin effect. In the drawings, the circular areas represent cross-sections of the busbar and the shading of the respective cross-sections indicate the distribution of current. The darker areas in the cross-sections correspond to higher current flow.

As illustrated in the first drawing from the left in the drawings, when a direct current flows through the conductor, the current distribution is uniform at the surface and the center of the conductor. In contrast, when an alternating current flows through the conductor, as illustrated in the second to fourth drawings from the left in the drawings, the current concentrates on the surface of the conductor due to the skin effect, and the further an area is from the surface of the conductor (the closer an area is to the center of the conductor cross-section), the less current flows. The tendency for the current to concentrate on the surface of the conductor increases as the frequency of the alternating current increases, and decreases the measurement accuracy of the current sensor 10.

FIG. 5 is a schematic view illustrating a mechanism of how the plate-shaped conductor 14 acts on the busbar 12. For the sake of convenience in describing the mechanism of action, the busbar 12 is illustrated as a cylindrical member having a circular cross-section in the drawings . In addition, the arrows in the drawings schematically indicate the current flowing inside the busbar 12, and the longer the arrows, the larger the current flowing.

As illustrated in (a1) in the upper section (FIG. 5(a1) to (a4)) in the drawing, when an alternating current I as a current to be measured flows through the busbar 12, a magnetic field H is generated inside and around the busbar 12 (a2). This magnetic field H induces an eddy current I_{E} inside the busbar 12, and the eddy current I_{E} generates a magnetic field H_{E} (a3). The eddy current I_{E} flows in the opposite direction to the alternating current I at the center of the busbar 12, and in the same direction as the alternating current I at the surface of the busbar 12. Due to the eddy current I_{E}, the further an area is from the surface of the busbar 12, that is, the closer the area is to the center, the less current flows. The magnetic sensor 13 (see FIGS. 2 and 3) measures a magnetic field H + H_{E}, which consists of the magnetic field H generated by the alternating current I and the magnetic field H_{E} generated by the eddy current I_{E}. The magnetic field H_{E} resulting from the eddy current I_{E} causes a measurement error of the current sensor 10, and increases as the frequency of the alternating current increases (a4).

Accordingly, as illustrated in the lower section (FIG. 5(b1) to (b4)) in FIG. 5, the influence of the magnetic field H_{E} caused by the eddy current I_{E} is reduced by disposing the plate-shaped conductor 14 in the vicinity of the surface of the busbar 12. Specifically, as illustrated in (b1) in the lower section, when an alternating current I as a current to be measured flows through the busbar 12, a magnetic field H is generated inside and around the busbar 12 (b2). This magnetic field H induces an eddy current I_{E}’ inside the conductor 14 disposed in the vicinity of the surface of the busbar 12, and the eddy current I_{E}’ generates a magnetic field H_{E}’ (b3). The direction of the magnetic field H_{E}’ generated by the eddy current I_{E}’ generated in the conductor 14 is opposite to that of the magnetic field H_{E} caused by the eddy current I_{E} generated in the busbar 12. Accordingly, the magnetic field H_{E}’ generated in the conductor 14 can cancel out all or part of the magnetic field H_{E} caused by the eddy current I_{E} in the busbar 12. That is, the magnetic field detected by the magnetic sensor 13 is a magnetic field H + H_{E} + H_{E}’, which is approximately equal to H, and thus the influence of the magnetic field H_{E} caused by the eddy current in the busbar 12 (b4) can be reduced.

In other words, by disposing the plate-shaped conductor 14 to face the busbar 12, the eddy current I_{E}’ flowing in the opposite direction to the eddy current I_{E} generated in the busbar 12 is generated in the conductor 14, thereby canceling the influence of the eddy current I_{E} in the busbar 12 on the magnetic field H. Accordingly, the occurrence of phase delay when the frequency of a current to be measured flowing through the busbar 12 is high can be suppressed, and increased measurement accuracy of the current sensor 10 can be achieved.

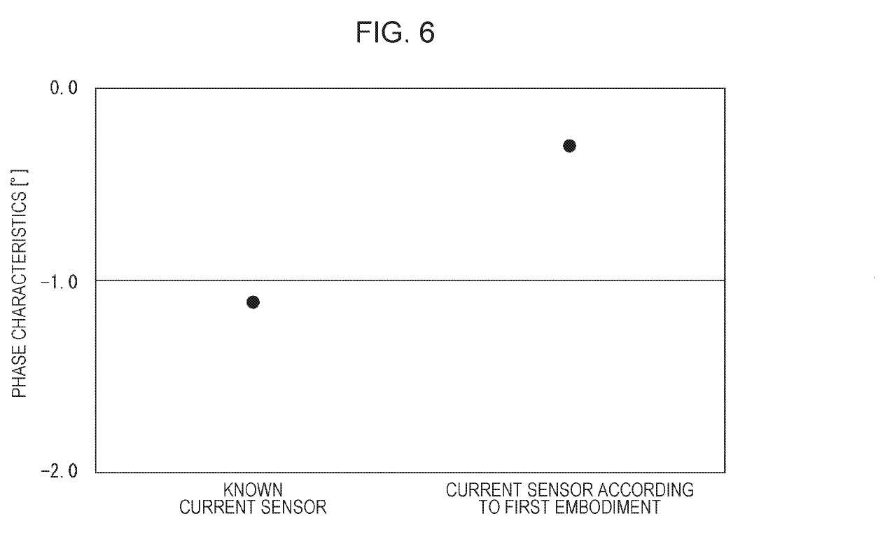

FIG. 6 is a graph showing simulation results of the phase characteristics of a known current sensor and the current sensor 10 according to the embodiment provided with the aluminum (Al) conductor 14. The known current sensor differs from the current sensor 10 according to the embodiment only in that the known current sensor is not provided with the conductor 14, and the configuration other than the conductor 14 is the same. In the simulation, the distance D (see FIG. 3) between the busbar 12 and the conductor 14 was set to 14 mm, and the frequency of the alternating current as the current to be measured flowing through the busbar 12 was set to 1 kHz. The simulation results in FIG. 6 show that the current sensor 10 exhibited better phase characteristics than the known current sensor, and it was found that the conductor 14 significantly improved the phase characteristics of the current sensor. It should be noted that the distance D refers to the distance between the respective center points of the busbar 12 and the conductor 14 in the Z direction.

### Second Embodiment

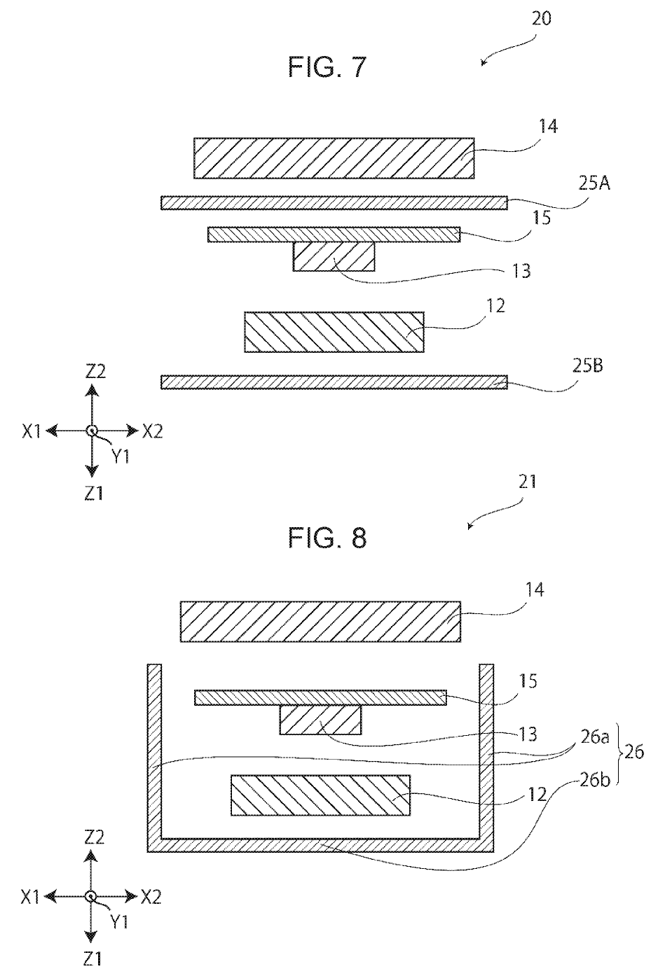

FIG. 7 is a cross-sectional view schematically illustrating a configuration of a current sensor 20 according to the embodiment. As illustrated in the drawing, the current sensor 20 differs from the current sensor 10 according to the first embodiment in that the current sensor 20 includes magnetic shield plates 25A and 25B. The current sensor 20 provided with the magnetic shield plates 25A and 25B enables suppression of magnetic noise and reduction of output error.

Each of the magnetic shield plates 25A (first magnetic shield plate) and the magnetic shield plate 25B (second magnetic shield plate) in the current sensor 20 is a plate-shaped magnetic shield having a plane parallel to the XY plane.

From the Z1 side toward the Z2 side in the Z direction, the magnetic shield plate 25B, the busbar 12, the magnetic sensor 13, the substrate 15, the magnetic shield plate 25A, and the conductor 14 are disposed in this order.

With the configuration in which the magnetic shield plate 25A is disposed between the magnetic sensor 13 and the conductor 14, the distance between the magnetic shield plate 25A and the magnetic sensor 13 becomes shorter. Accordingly, the magnetic shield plate 25A provides higher effectiveness in shielding magnetic noise.

With the configuration in which the magnetic sensor 13 and the busbar 12 are disposed between the magnetic shield plate 25A and the magnetic shield plate 25B, magnetic noise from the Z1 direction and the Z2 direction to the magnetic sensor 13 can be suppressed, and magnetic noise can be effectively shielded. However, the present invention may also be implemented in a configuration in which only one of the magnetic shield plates 25A and 25B is provided.

The magnetic shield plates 25A and 25B include, for example, a plurality of metal plates of the same shape that are stacked. It is preferable that the magnetic shield plates 25A and 25B be made of a material having a lower electrical resistance than that of the conductor 14.

### Modification

FIG. 8 is a cross-sectional view schematically illustrating a current sensor 21 according to a modification.

The current sensor 21 differs from the current sensor 20 in that, when viewed in the Y direction (second direction), the current sensor 21 includes a U-shaped magnetic shield 26, instead of the pair of magnetic shield plates 25A and 25B.

The magnetic shield 26 has side wall portions 26a and 26a spaced apart on both sides of the magnetic sensor 13 and the busbar 12 in the X-direction (third direction), and a bottom portion 26b disposed opposite the magnetic sensor 13 with the busbar 12 between the bottom portion 26b and the magnetic sensor 13.

The bottom portion 26b is formed in a plate-like shape having a plate surface parallel to the XY plane and is disposed on the Z1 side in the Z direction relative to the busbar 12 so as to face the busbar 12. The side wall portions 26a and 26a are plates having plate surfaces parallel to the YZ plane, and extend from each of the two ends of the bottom portion 26b in the X direction toward the Z2 side in the Z direction.

As illustrated in FIG. 8, the magnetic sensor 13 is disposed between the side wall portions 26a and 26a of the magnetic shield 26. In other words, when viewed in the X direction, the magnetic sensor 13 and the side wall portions 26a and 26a are disposed to overlap each other. Accordingly, by disposing the magnetic sensor 13 between the side wall portions 26a and 26a, the magnetic shield 26 can effectively suppress disturbance magnetic fields acting on the magnetic sensor 13.

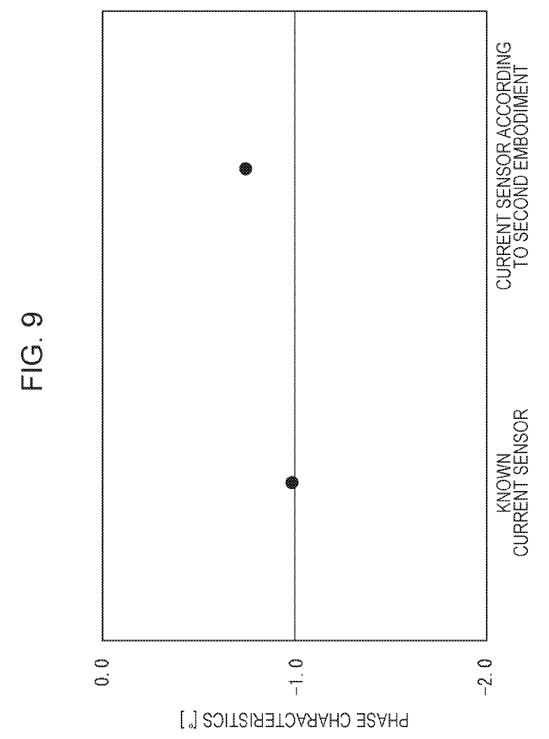

FIG. 9 is a graph showing simulation results of the phase characteristics of a known current sensor and the current sensor 20 according to the embodiment illustrated in FIG. 7. The known current sensor differs from the current sensor 20 only in that the known current sensor is not provided with the conductor 14, and the other configurations are same. As a result of a simulation conducted with the frequency of the alternating current as the current to be measured flowing through the busbar 12 set to 1 kHz and the distance D (see FIG. 3) between the busbar 12 and the conductor 14 set to 14 mm, the current sensor 20 exhibited better phase characteristics than the known current sensor. This result suggests that also in the current sensor 20 provided with the magnetic shield plates 25A and 25B, the phase characteristics can be improved by providing the conductor 14.

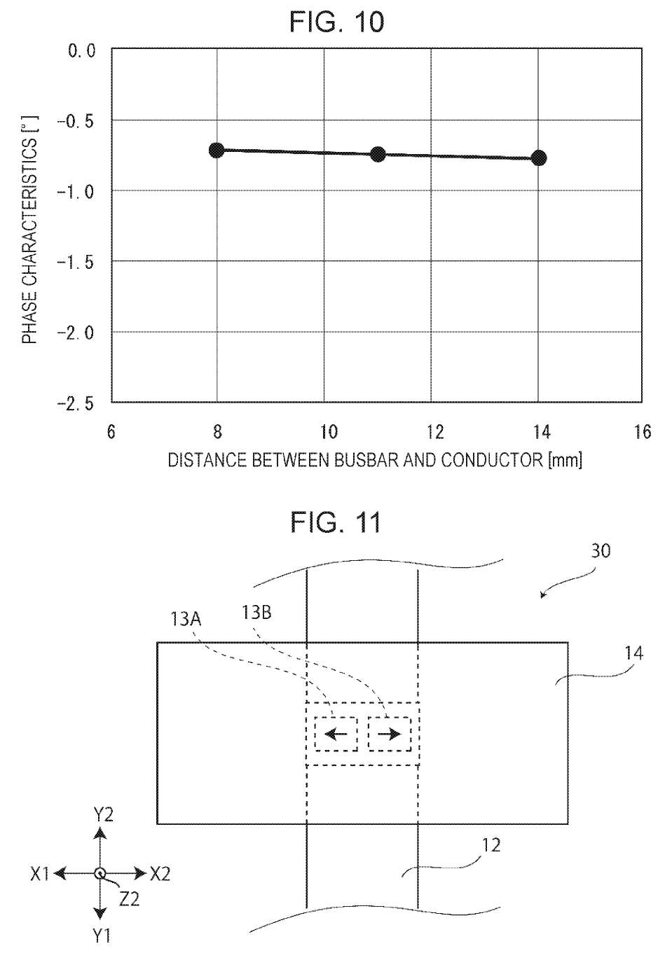

FIG. 10 is a graph showing simulation results indicating the relationship between the distance D between the busbar 12 and the conductor 14 and the phase characteristics in the current sensor 20. The graph in FIG. 10 shows the results obtained by evaluating phase characteristics of the current sensor 20 by simulation conducted by varying the distance D between the busbar 12 and the conductor 14, with the frequency of the alternating current flowing through the busbar 12 set to 1 kHz.

The results shown in FIG. 10 indicate that, at least within the range in which the distance D between the busbar 12 and the conductor 14 is 8 mm to 14 mm, the phase characteristics became slightly better as the distance D decreased, but there was no significant difference depending on the distance D. In the current sensor 20, the distance D in the Z direction between the busbar 12 and the cover section 17 is normally within 16 mm. Accordingly, the phase characteristics of the current sensor 20 can be increased by the conductor 14 provided on the Z2-side surface, which is the side opposite to the busbar 12, of the cover section 17 (see FIGS. 7 and 1).

### Third embodiment

In this embodiment, in a configuration provided with a pair of magnetic sensors 13A and 13B, current sensors 30, 31, and 32, which differ from the current sensors 10 and 20, will be described below.

FIG. 11 is a plan view schematically illustrating a configuration of the current sensor 30 according to the embodiment. As illustrated in the drawing, the current sensor 30 includes the pair of magnetic sensors 13A and 13B whose detection directions are opposite to each other. With this configuration, a magnetic field generated by the busbar 12 can be detected as the difference between magnetic fields detected by the pair of magnetic sensors 13A and 13B. By using the difference between the magnetic fields detected by the pair of magnetic sensors 13A and 13B, the influence of magnetic noise can be reduced, and thus the measurement accuracy of the current sensor 30 can be increased.

For example, the geomagnetic field exerts an equal influence on the pair of magnetic sensors 13A and 13B. Accordingly, by using an operational output as the difference between magnetic fields detected by the pair of magnetic sensors 13A and 13B, the influence of the geomagnetic field can be removed from the outputs of the magnetic sensors 13A and 13B. In addition, many types of magnetic noise other than the geomagnetic field exert influences of substantially the same degree and in the same direction on the magnetic sensors 13A and 13B. Therefore, by using operational outputs, the influences of magnetic noise can be suppressed, and the measurement accuracy of the current sensor 30 can be increased.

It should be noted that, in the detection directions indicated by the arrows in FIG. 11, the detection direction of the magnetic sensor 13A is the X1 direction and the detection direction of the magnetic sensor 13B is the X2 direction. However, the detection direction of the magnetic sensor 13A may be the X2 direction and the detection direction of the magnetic sensor 13B may be the X1 direction. In addition, while the current sensor 30 providing the two detection points at which the magnetic sensors 13A and 13B are provided respectively has been described, the number of detection points may be three or more.

### Modifications

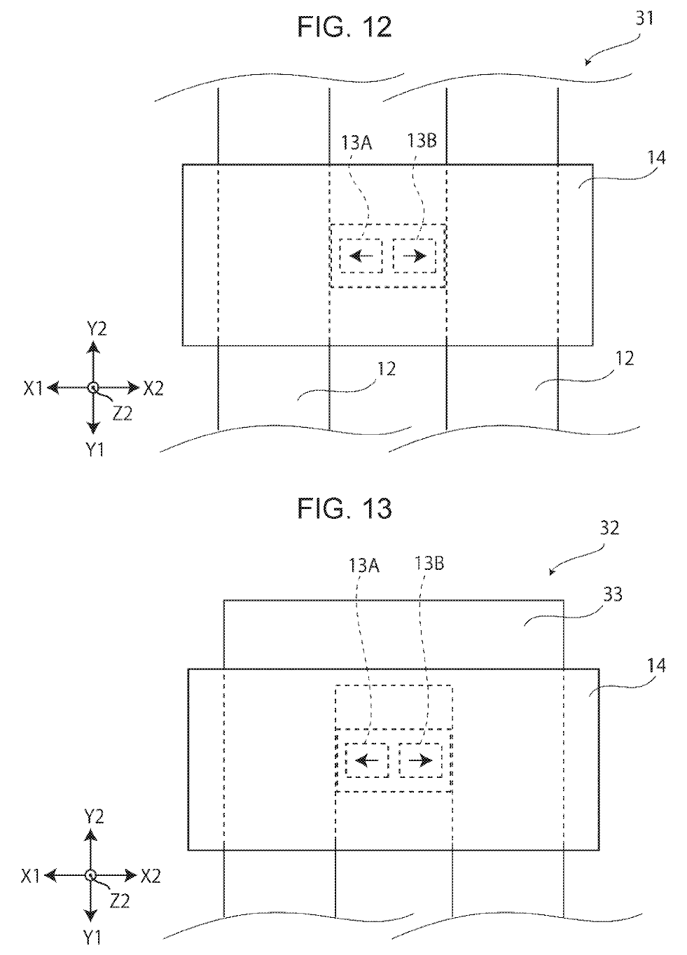

FIG. 12 is a plan view schematically illustrating a configuration of the current sensor 31 according to a modification. As illustrated in the drawing, the current sensor 31 includes two busbars 12, and when viewed in the Z direction, the magnetic sensors 13A and 13B are disposed between the two busbars 12. With this configuration, the currents to be measured flowing through the two busbars 12 can be accurately detected respectively by using operational outputs of the magnetic sensors 13A and 13B.

FIG. 13 is a plan view schematically illustrating a configuration of the current sensor 32 according to another modification. As illustrated in the drawing, the current sensor 32 includes a U-shaped busbar 33 when viewed in the Z direction, and the magnetic sensors 13A and 13B are disposed between two portions of the busbar 33 extending parallel to each other. With this configuration, the current to be measured flowing through the busbar 33 can be accurately detected by using operational outputs of the magnetic sensors 13A and 13B.

The embodiments disclosed in this specification are in all respects illustrative and not limited to these embodiments. The scope of the invention is not limited to the embodiments described above, but is defined by the claims, and is intended to include all modifications within the meaning and scope equivalent to the claims.

The present invention is useful, for example, as a current sensor that measure currents to be measured flowing through various devices to control power systems of vehicles or the like equipped with these devices.

What is claimed is:

1. A current sensor including a busbar through which a current to be measured flows and a magnetic sensor disposed to detect a magnetic field generated by the busbar, the current sensor comprising:
a conductor comprising a nonmagnetic material and facing the busbar, wherein
the conductor is disposed opposite the busbar with the magnetic sensor interposed between the conductor and the busbar such that, when the busbar is energized, a magnetic field generated by an eddy current generated in the conductor cancels out at least part of a magnetic field generated by an eddy current generated in the busbar, at the position the magnetic sensor is disposed.

2. The current sensor according to claim 1, wherein when a direction in which the busbar, the magnetic sensor, and the conductor are disposed is a first direction, a direction orthogonal to the first direction and in which the busbar extends is a second direction, and a direction orthogonal to the first direction and the second direction is a third direction,
the conductor is formed in a plate-like shape parallel to a plane defined by the second direction and the third direction.

3. The current sensor according to claim 2, wherein when viewed in the first direction, the busbar and the magnetic sensor are disposed inside ends of the conductor in the third direction.

4. The current sensor according to claim 1, wherein the nonmagnetic material is aluminum.

5. The current sensor according to claim 1, further comprising a magnetic shield facing the busbar.

6. The current sensor according to claim 5, wherein
the magnetic shield comprises a plate-shaped first magnetic shield plate, and
the first magnetic shield plate is disposed between the magnetic sensor and the conductor.

7. The current sensor according to claim 5, wherein
the magnetic shield comprises a plate-shaped first magnetic shield plate and a plate-shaped second magnetic shield plate, and
the magnetic sensor and the busbar are disposed between the first magnetic shield plate and the second magnetic shield plate.

8. The current sensor according to claim 5, wherein
when a direction in which the busbar, the magnetic sensor, and the conductor are disposed is a first direction, a direction in which the busbar extends is a second direction, and a direction orthogonal to the first direction and the second direction is a third direction,
the magnetic shield
has a U shape when viewed in the second direction, and
has side wall portions spaced apart on both sides of the magnetic sensor and the busbar in the third direction, and a bottom portion disposed opposite the magnetic sensor in the first direction with the busbar interposed between the bottom portion and the magnetic sensor.

9. The current sensor according to claim 1, wherein
the magnetic sensor comprises a pair of magnetic sensors whose detection directions are opposite to each other, and
the magnetic field generated by the busbar is detected as a difference between magnetic fields detected by the pair of magnetic sensors.
